(19) United States
(12) Patent Application Publication
(10) Pub. No.: US 2026/0262382 A1
(43) Pub. Date: Sep. 3, 2026

(54) DISPLAY PANEL, ELECTRONIC DEVICE INCLUDING THE SAME, AND METHOD OF MANUFACTURING THE DISPLAY PANEL

(71) Applicant: Samsung Display Co., Ltd., Yongin-si (KR)

(72) Inventors: CHANGHO YI, Yongin-si (KR); DAWOON JUNG, Yongin-si (KR)

(21) Appl. No.: 19/408,668

(22) Filed: Dec. 4, 2025

(30) Foreign Application Priority Data
Feb. 28, 2025 (KR) 10-2025-0026350
Jun. 5, 2025 (KR) 10-2025-0073655

(51) Int. Cl. H10K 59/121; H10D 86/01; H10D 86/40; H10D 86/60; H10K 59/12; H10K 59/124; H10K 59/131

(52) U.S. Cl. CPC H10K 59/1213; H10D 86/0221; H10D 86/423; H10D 86/441; H10D 86/60; H10K 59/1201; H10K 59/124; H10K 59/1315

(57) ABSTRACT

A display panel includes a base layer, a circuit element layer, and a light-emitting element layer including a light-emitting element, wherein the circuit element layer includes a conductive pattern, a first insulating layer above the conductive pattern, a second insulating layer above the first insulating layer, a first transistor including a first semiconductor pattern above the second insulating layer, and a first gate, a third insulating layer covering the first semiconductor pattern, a fourth insulating layer covering the first gate, a bridge pattern between the second insulating layer and the first semiconductor pattern, and including molybdenum or titanium, a contact hole penetrating through the first to fourth insulating layers, and exposing a portion of the bridge pattern and a portion of the conductive pattern, and a connection pattern in the contact hole and electrically connecting the bridge pattern and the conductive pattern.

### CROSS-REFERENCE TO RELATED APPLICATION(S)

The present application claims priority to, and the benefit of, Korean Patent Application No. 10-2025-0026350, filed on February 28, 2025, and Korean Patent Application No. 10-2025-0073655, filed on June 5, 2025, in the Korean Intellectual Property Office, the entire disclosures of which are incorporated herein by reference.

### BACKGROUND

### 1. Field

The present disclosure relates to a high-resolution display panel with improved reliability, an electronic device including the display panel, and a method of manufacturing the display panel.

### 2. Description of the Related Art

Multimedia electronic devices, such as televisions, mobile phones, tablet computers, navigation devices, and game devices, include a display panel to display images. The display panel includes pixels to display images.

Recently, demand for high-resolution electronic devices has been increasing. The resolution of an electronic device increases as the number of pixels arranged in a display panel increases. To increase the number of pixels, technological development may suitably reduce the size of the pixels.

### SUMMARY

The present disclosure provides a high-resolution display panel with improved reliability and an electronic device including the display panel.

The present disclosure provides a method of manufacturing the high-resolution display panel with improved reliability.

Embodiments of the present disclosure provide a display panel including a base layer, a circuit element layer above the base layer, and a light-emitting element layer including a light-emitting element above the circuit element layer, wherein the circuit element layer includes a conductive pattern above the base layer, a first insulating layer above the conductive pattern, a second insulating layer above the first insulating layer, a first transistor including a first semiconductor pattern above the second insulating layer, and a first gate overlapping the first semiconductor pattern, a third insulating layer covering the first semiconductor pattern, a fourth insulating layer covering the first gate, a bridge pattern between the second insulating layer and the first semiconductor pattern, and including molybdenum (Mo) or titanium (Ti), a contact hole penetrating through the first insulating layer, the second insulating layer, the third insulating layer, and the fourth insulating layer, and exposing a portion of the bridge pattern and a portion of the conductive pattern, and a connection pattern in the contact hole and electrically connecting the bridge pattern and the conductive pattern.

The bridge pattern may include a first bridge portion covered by the third insulating layer, and a second bridge portion exposed through the contact hole, and having a thickness that is less than a thickness of the first bridge portion.

The thickness of the first bridge portion may be greater than a thickness of the first semiconductor pattern.

The first semiconductor pattern may contact the first bridge portion.

The second insulating layer may include a first insulation portion that does not overlap the bridge pattern, and a second insulation portion overlapping the bridge pattern, and having at thickness that is greater than a thickness of the first insulation portion.

The connection pattern may be spaced apart from the first semiconductor pattern.

The connection pattern may be electrically connected to the first semiconductor pattern via the bridge pattern.

The first semiconductor pattern may include an oxide semiconductor.

The first semiconductor pattern may include indium gallium zinc oxide (IGZO).

The first insulating layer may include silicon nitride, wherein the second insulating layer includes silicon oxide.

Embodiments of the present disclosure provide an electronic device including a display panel including a base layer, a circuit element layer above the base layer, and a light-emitting element layer including a light-emitting element above the circuit element layer, and a housing accommodating the display panel, wherein the circuit element layer including a conductive pattern above the base layer, a first insulating layer above the conductive pattern, a second insulating layer above the first insulating layer, and including a first insulation portion, and a second insulation portion having a thickness that is greater than a thickness of the first insulation portion, a first transistor including a first semiconductor pattern above the second insulating layer, and a first gate overlapping the first semiconductor pattern, a third insulating layer covering the first semiconductor pattern, a fourth insulating layer covering the first gate, a bridge pattern between the second insulating layer and the first semiconductor pattern, not overlapping the first insulation portion, overlapping the second insulation portion, and including a first bridge portion covered by the third insulating layer, and a second bridge portion having a thickness that is less than a thickness of the first bridge portion, a contact hole penetrating through the first insulating layer, the second insulating layer, the third insulating layer, and the fourth insulating layer, and exposing the second bridge portion and a portion of the conductive pattern, and a connection pattern in the contact hole, and electrically connecting the bridge pattern and the conductive pattern.

The bridge pattern may include molybdenum (Mo) or titanium (Ti), wherein the first semiconductor pattern includes an oxide semiconductor, wherein the first insulating layer includes silicon nitride, and wherein the second insulating layer includes silicon oxide.

The connection pattern may be electrically connected to the first semiconductor pattern via the bridge pattern.

The electronic device may further include at least one of a processor, a memory, or a power module.

The electronic device may include a television, a monitor, an outdoor billboard, a personal computer, a notebook computer, a personal digital assistant, a car dashboard, a center fascia, a navigation unit, a room mirror display, a game unit, a smartphone, a tablet computer, a smart watch, a smart glasses, a head-mounted display, or a camera.

Embodiments of the present disclosure provide a method of manufacturing a display panel, the method including forming a preliminary bridge pattern including molybdenum (Mo) or titanium (Ti) on a preliminary display panel including a base layer, a conductive pattern above the base layer, a first insulating layer above the conductive pattern, and a second insulating layer above the first insulating layer, forming a first semiconductor pattern including an oxide semiconductor above the second insulating layer to contact the preliminary bridge pattern, forming a third insulating layer to cover the preliminary bridge pattern and the first semiconductor pattern, forming a first gate above the third insulating layer to overlap with the first semiconductor pattern, forming a fourth insulating layer to cover the first gate, forming a preliminary contact hole through the fourth insulating layer and the third insulating layer to expose a portion of the preliminary bridge pattern and a portion of the second insulating layer, and forming a contact hole through the second insulating layer and the first insulating layer from the preliminary contact hole to expose a portion of the conductive pattern and a portion of a bridge pattern formed from the exposed portion of the preliminary bridge pattern.

The method may further include forming a connection pattern in the contact hole to electrically connect the bridge pattern and the conductive pattern.

The forming of the preliminary bridge pattern may include depositing a bridge metal layer above the second insulating layer, dry-etching the bridge metal layer to pattern the bridge metal layer, and cleaning the bridge metal layer, wherein a first insulation portion of the second insulating layer, which is exposed without being covered by the preliminary bridge pattern, is etched in the cleaning, and has a thickness that is less than a second insulation portion of the second insulating layer, which is covered by the preliminary bridge pattern.

The preliminary contact hole may be spaced from the first semiconductor pattern in the forming of the preliminary contact hole.

The portion of the preliminary bridge pattern, which is exposed through the preliminary contact hole, may be substantially simultaneously etched with the second insulating layer or the first insulating layer in the forming of the contact hole.

According to the above, because the semiconductor pattern is not exposed through the contact hole, and because the bridge pattern, which is connected to the semiconductor pattern, is exposed instead, contact resistance is reduced, and occurrence of cracks is reduced or prevented. Thus, the display panel and the electronic device including the display panel have excellent reliability.

According to the method of manufacturing the display panel, as the contact hole is formed to expose the bridge pattern, which is connected to the semiconductor pattern, while not exposing the semiconductor pattern, contact resistance is reduced and occurrence of cracks is reduced or prevented. Thus, the display panel with excellent reliability is manufactured.

### BRIEF DESCRIPTION OF THE DRAWINGS

FIG. 1 is a block diagram of an electronic device according to one or more embodiments of the present disclosure;

FIG. 2 is a schematic view of various electronic devices according to embodiments of the present disclosure;

FIG. 3A is an assembled perspective view of an electronic device according to one or more embodiments of the present disclosure;

FIG. 3B is an exploded perspective view of an electronic device according to one or more embodiments of the present disclosure;

FIG. 4A is an assembled perspective view of an electronic device according to one or more embodiments of the present disclosure;

FIG. 4B is an exploded perspective view of an electronic device according to one or more embodiments of the present disclosure;

FIG. 5 is a cross-sectional view of a display module according to one or more embodiments of the present disclosure;

FIG. 6 is an equivalent circuit diagram of a pixel according to one or more embodiments of the present disclosure;

FIG. 7A is a cross-sectional view of a display panel according to one or more embodiments of the present disclosure;

FIG. 7B is a cross-sectional view of an area AA’ of FIG. 7A; and

FIGS. 8 to 14 are cross-sectional views showing processes of a manufacturing method of a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

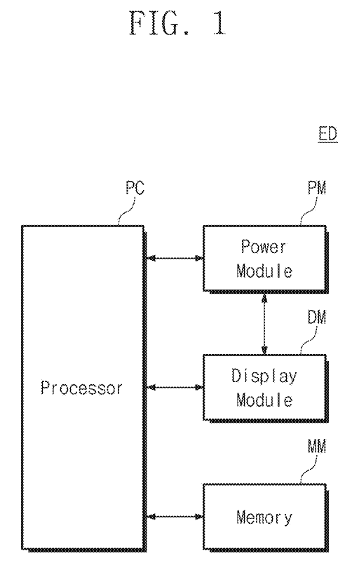

FIG. 1 is a block diagram of an electronic device ED according to one or more embodiments of the present disclosure.

Referring to FIG. 1, the electronic device ED may include a display module DM, a processor PC, a memory MM, and a power module PM.

The processor PC may include at least one of a central processing unit (CPU), an application processor (AP), a graphics processing unit (GPU), a communication processor (CP), an image signal processor (ISP), or a controller.

The memory MM may store data information suitable for the operation of the processor PC or the display module DM. When the processor PC executes an application stored in the memory MM, an image data signal and/or an input control signal may be transmitted to the display module DM, and the display module DM may process the received signals to output image information through a display screen.

The power module PM may include a power supply module, such as a power adapter or a battery device, and a power conversion module that converts power supplied by the power supply module to generate power suitable for the operation of the electronic device ED.

At least one of the above-described components of the electronic device ED may be included in electronic devices according to embodiments described below. In addition, among individual modules that are functionally included within a single module, some may be included in the electronic device while others may be provided separately from the electronic device. As an example, the electronic device may include the display module DM, and the processor PC, the memory MM, and the power module PM may be provided as separate devices other than the electronic device.

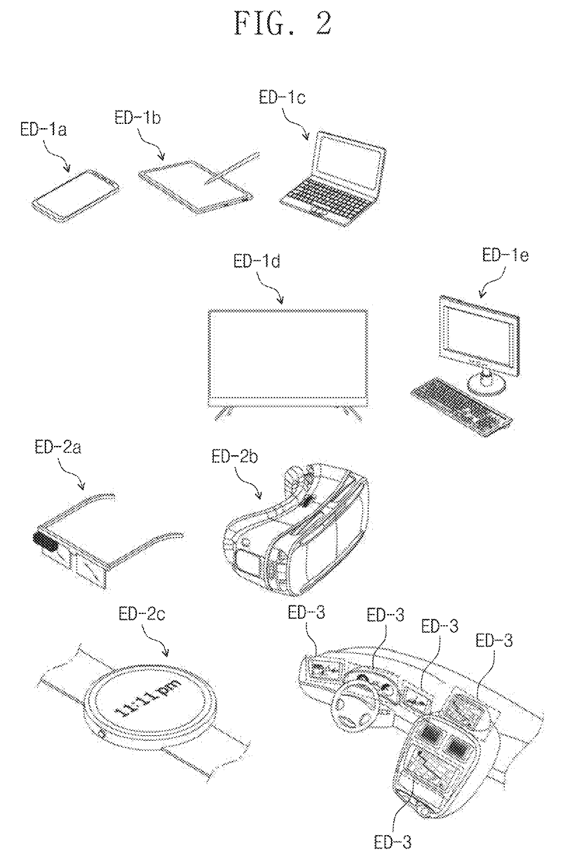

FIG. 2 is a schematic view illustrating various electronic devices ED-1a, Ed-1b, ED-1c, ED-1d, ED-1e, ED-2a, ED-2b, ED-2c, and ED-3 according to embodiments of the present disclosure.

Referring to FIG. 2, various electronic devices to which the display module DM (refer to FIG. 1) according to the embodiments of the present disclosure is applied may include not only an electronic device to display images, such as a smartphone ED-1a, a tablet PC ED-1b, a laptop computer ED-1c, a television ED-1d, a desktop monitor ED-1e, etc., but also may include a wearable electronic device, such as a smart glasses ED-2a, a head-mounted display ED-2b, a smartwatch ED-2c, etc., and may include an in-vehicle electronic device ED-3, such as an instrument panel, a center fascia, a dashboard-mounted center information display (CID), or a room mirror display.

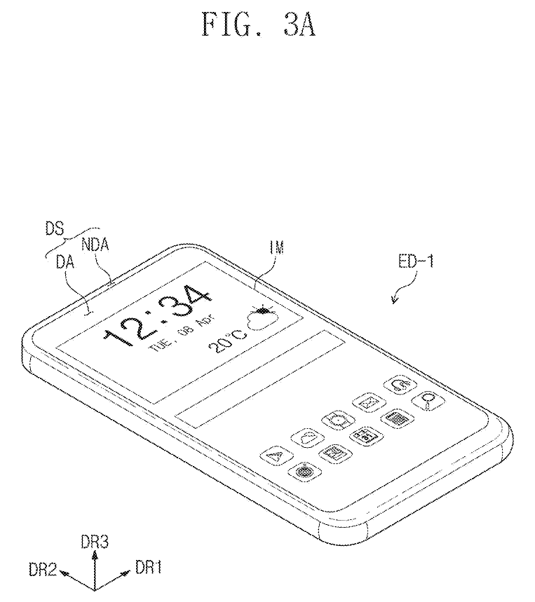

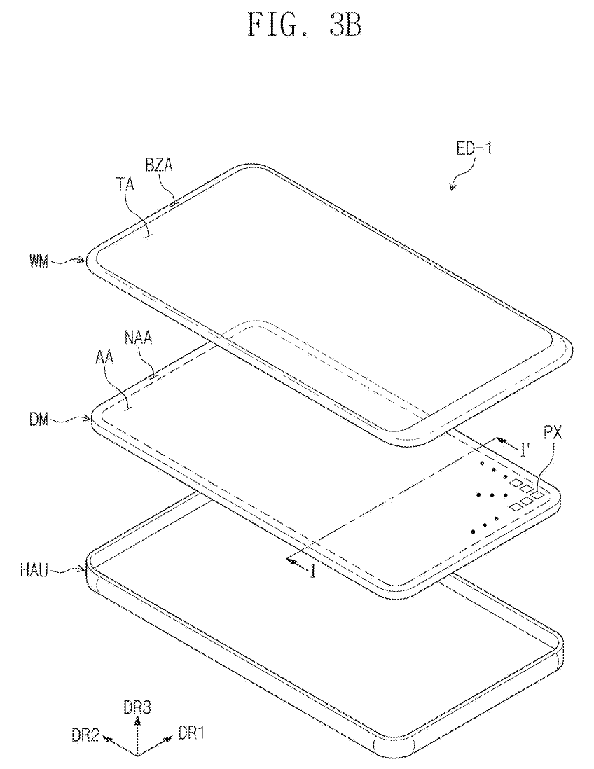

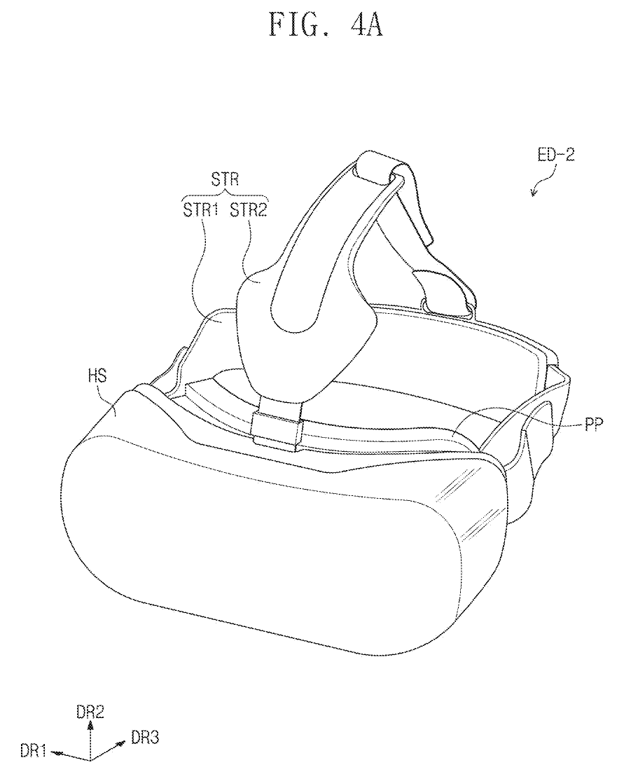

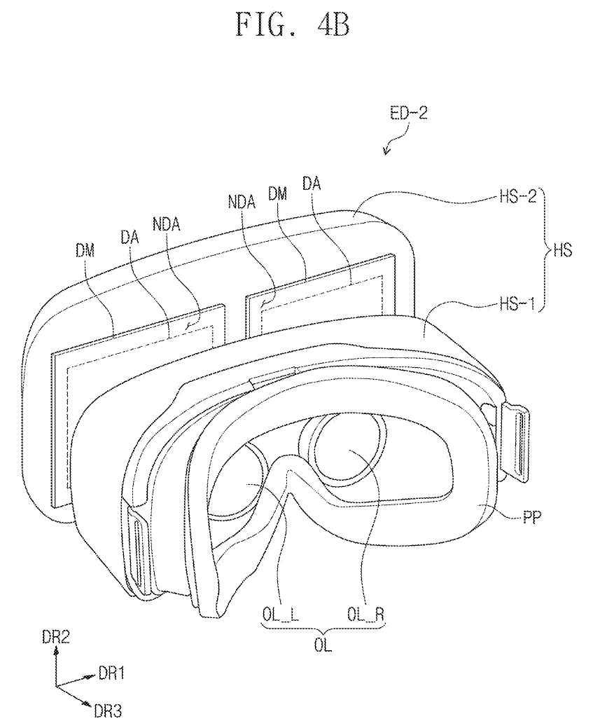

FIG. 3A is an assembled perspective view of an electronic device ED-1 according to one or more embodiments of the present disclosure. FIG. 3B is an exploded perspective view of the electronic device ED-1 according to one or more embodiments of the present disclosure. FIG. 4A is an assembled perspective view of an electronic device ED-2 according to one or more embodiments of the present disclosure. FIG. 4B is an exploded perspective view of the electronic device ED-2 according to one or more embodiments of the present disclosure.

The electronic devices ED-1 and ED-2 may be activated in response to electrical signals. As an example, the electronic devices ED-1 and ED-2 may be a large-sized electronic device, such as a television set, a monitor, an outdoor billboard, etc. In addition, the electronic devices ED-1 and ED-2 may be a small and medium-sized electronic device, such as a personal computer, a notebook computer, a personal digital assistant, a car navigation unit, a game unit, a mobile phone, a tablet computer, a camera, etc. However, these are merely examples, and the electronic devices ED-1 and ED-2 should not be limited thereto or thereby. FIGS. 3A and 3B show the mobile phone as an example of the electronic device ED-1, and FIGS. 4A and 4B show a wearable display device as an example of the electronic device ED-2.

The electronic devices ED-1 and ED-2 may be rigid or flexible. The term “flexible” used herein refers to the property of being able to be bent. For example, the electronic devices ED-1 and ED-2 that are flexible may be a curved device, a rollable device, or a foldable device.

In FIG. 3A and the following drawings, a first direction DR1, a second direction DR2, and a third direction DR3 are shown, and in the present disclosure, directions indicated by the first, second, and third directions DR1, DR2, and DR3 are relative to each other and may be changed to other directions. In addition, directions opposite to the directions indicated by the first, second, and third directions DR1, DR2, and DR3 may also be described as the first, second, and third directions DR1, DR2, and DR3, and may be assigned with the same reference numerals as the first, second, and third directions DR1, DR2, and DR3.

Referring to FIG. 3A, the electronic device ED-1 may include a display surface DS defined by the first direction DR1 and the second direction DR2 crossing the first direction DR1. The electronic device ED-1 may provide an image IM to a user through the display surface DS. The electronic device ED-1 may display the image IM toward the third direction DR3 on the display surface DS, the display surface DS being substantially parallel to each of the first direction DR1 and the second direction DR2. In the present disclosure, front (or upper) and rear (or lower) surfaces of each component may be defined with respect to a direction in which the image IM is displayed. The front surface and the rear surface may be opposite to each other in the third direction DR3, and a normal line direction of each of the front and rear surfaces may be substantially parallel to the third direction DR3.

The display surface DS may include a display area DA and a non-display area NDA adjacent to the display area DA. The non-display area NDA may be an area in which the image IM is not displayed. However, the present disclosure should not be limited thereto or thereby, and the non-display area NDA may be omitted.

The electronic device ED-1 may sense an external input applied from the outside. The external input may include a variety of external inputs provided from the outside of the electronic device ED-1. For example, the external input may include an external input (e.g., a hovering input) applied when in proximity to or approaching the electronic device ED-1 within a selected distance, as well as a touch input from a part of the user's body (e.g., a user’s hand). In addition, the external input may take various forms, such as force, pressure, temperature, or light.

The electronic device ED-1 may further include various electronic modules. For example, the electronic module may include at least one of a camera, a speaker, an optical sensor, or a thermal sensor. The electronic module may sense an external object through the display surface DS, or may provide a sound signal, such as a voice, to the outside through the display surface DS. The electronic module may include a plurality of components, although the present disclosure should not be limited to any particular embodiment.

Referring to FIG. 3B, the electronic device ED-1 may include a display module DM and a window WM located on the display module DM. The window WM may be located on at least one of upper or lower portions of the display module DM. FIG. 3B shows a structure in which the window WM is located on the upper portion of the display module DM.

In addition, the electronic device ED-1 may further include an electronic module located under the display module DM. As an example, the electronic module may include a camera module.

Further, the electronic device ED-1 may further include an adhesive layer and/or a polarizing film located between the display module DM and the window WM. In addition, the electronic device ED-1 may further include a lower functional layer located under the display module DM

The electronic device ED-1 may further include a housing HAU that accommodates the display module DM and the lower functional layer. The housing HAU may be coupled with the window WM to form an exterior of the electronic device ED-1. The housing HAU may include a material with a relatively high rigidity. For example, the housing HAU may include a plurality of frames and/or plates formed of a glass, plastic, metal material, or combinations thereof. The display module DM may be accommodated in an accommodation space and may be protected from external impacts.

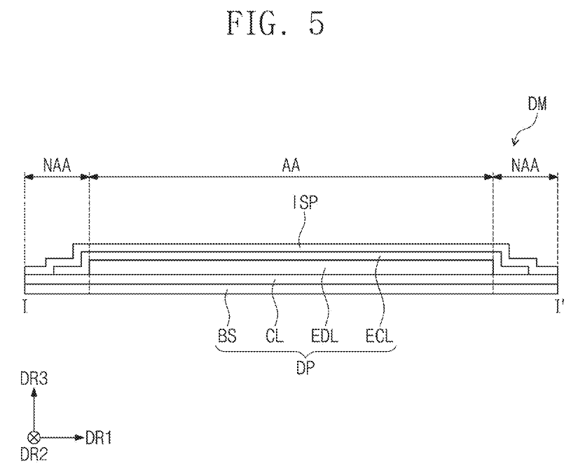

The display module DM may display the image IM (refer to FIG. 3A) in response to electrical signals, and may transmit and receive information about the external input. The display module DM may include a display panel DP (refer to FIG. 5).

The display module DM may include an active area AA and a peripheral area NAA. The active area AA may be an area through which the image IM (refer to FIG. 3A) is provided. A pixel PX may be located in the active area AA. The peripheral area NAA may be adjacent to the active area AA. The peripheral area NAA may surround the active area AA (e.g., in plan view). A driving circuit or a driving line to drive the active area AA may be arranged in the peripheral area NAA.

The display module DM may include a plurality of pixels PX. Each of the pixels PX may emit light in response to an electrical signal. The lights emitted by the pixels PX may form the image IM (refer to FIG. 3A). Each of the pixels PX may include a display element. For example, the display element may be an organic light-emitting element, an inorganic light-emitting element, an organic-inorganic light-emitting element, a micro-LED, a nano-LED, a quantum dot light-emitting element, an electrophoretic element, an electrowetting element, or the like.

The window WM may entirely cover an upper surface of the display module DM. The window WM may have a shape corresponding to a shape of the display module DM. The window WM may have flexibility, allowing it to be deformed according to the folding or bending of the electronic device ED-1. The window WM may protect the display module DM from external impacts.

The window WM may include a transmission area TA and a bezel area BZA. The transmission area TA may overlap with at least a portion of the active area AA of the display module DM. The transmission area TA may be an optically transparent area. For example, the transmission area TA may have a transmittance of about 90% or more with respect to a wavelength of a visible light region. The image IM (refer to FIG. 3A) may be provided to the user through the transmission area TA, and the user may receive information from the image IM (refer to FIG. 3A).

The bezel area BZA may be an area having a relatively lower transmittance than the transmission area TA. The bezel area BZA may define a shape of the transmission area TA. The bezel area BZA may have a selected color. The bezel area BZA may cover the peripheral area NAA of the display module DM to reduce or prevent visibility of the peripheral area NAA from the outside. However, this is merely an example, and the bezel area BZA may be omitted from the window WM.

The electronic device ED-2 shown in FIGS. 4A and 4B may be a wearable device that is activated in response to electronic signals. The wearable device may be a device that is worn on the body of a user and may include a head-mounted display (HMD) that implements extended reality (XR). FIGS. 4A and 4B show the head-mounted display as an example of the electronic device ED-2, although the present disclosure should not be limited thereto or thereby.

The electronic device ED-2 shown in FIGS. 4A and 4B may be a display device that is worn on a head of the user. The electronic device ED-2 may provide images while blocking the user’s actual surrounding view. The user wearing the electronic device ED-2 may be more easily immersed in virtual reality.

The electronic device ED-2 may include a body part HS, a strap part STR, a cushion part PP, and a display module DM. In one or more embodiments, the electronic device ED-2 may include a variety of sensors and a camera.

The body part HS may be worn on the user’s head. In one or more embodiments, the display module DM displaying the images, an acceleration sensor, etc., may be accommodated inside the body part HS. The acceleration sensor may detect the user’s movement, and may transmit a signal to the display module DM. Accordingly, the display module DM may provide the images that correspond to changes in the user’s line of sight. Therefore, the user may experience a virtual reality that is like actual reality. The description of the display module DM from FIG. 3B may be applied in the same manner. In addition, the configuration of the display module DM included in the electronic device ED-2 may be provided with a different configuration from that shown in FIG. 3B to suit the characteristics of the wearable device.

The body part HS may accommodate components with various functions in addition to the above-described components. For instance, in one or more embodiments, a control part may be additionally placed on the exterior of the body part HS to adjust volume, screen brightness, or the like. The control part may be provided as a physical button or a touch sensor. In addition, in one or more embodiments, the body part HS may accommodate a proximity sensor to determine whether the user is wearing the electronic device ED-2. In addition, the body part HS may further include an external display panel.

The body part HS may include a main portion HS-1 and a cover portion HS-2. FIG. 4B shows a structure in which the main portion HS-1 is separated from the cover portion HS-2 as an example, although the present disclosure should not be limited thereto or thereby. For instance, the main portion HS-1 and the cover portion HS-2 may be provided as a single, integrated unit, and the main portion HS-1 and the cover portion HS-2 may not be separable from each other.

The display modules DM may be located between the main portion HS-1 and the cover portion HS-2. Each of the display modules DM may display the images through the active area AA. Each of the display modules DM may include the peripheral area NAA surrounding the active area AA. In one or more embodiments, the peripheral area NAA may be located only at one side of the active area AA, or may be omitted.

FIG. 4B illustrates an example where a left-eye image and a right-eye image are respectively provided by the display modules DM separated from each other, although the present disclosure should not be limited thereto or thereby. As an example, the left-eye image and the right-eye image may be displayed through one display module. The display modules DM may be driven by separate driving units, although the present disclosure should not be limited thereto or thereby. According to one or more embodiments, the display modules DM may be driven by a single driving unit. The display modules DM may generate the images corresponding to image data input thereto.

The strap part STR may be coupled with the body part HS to allow the body part HS to be easily worn by the user. The strap part STR may include a main strap STR1 and an upper strap STR2.

The main strap STR1 may be worn around the circumference of the user’s head. The main strap STR1 may secure the body part HS to the user so that the body part HS may fit closely against the user’s head. The upper strap STR2 may connect the body part HS to the main strap STR1 along an upper portion of the user’s head. The upper strap STR2 may reduce or prevent the likelihood of the body part HS slipping down. In addition, the upper strap STR2 may enhance the user’s wearing comfort by distributing the load of the body part HS.

The strap part STR may be modified into various shapes other than the shape disclosed in FIG. 4A as long as the strap part STR secures the body part HS to the user. As an example, according to one or more embodiments, the upper strap STR2 may be omitted. In addition, according to one or more embodiments, the strap part STR may be modified into various shapes, such as a helmet coupled to the body part HS or temples of glasses coupled to the body part HS.

The cushion part PP may be located between the body part HS and the user’s head. The cushion part PP may be formed of a material that is easily deformed into different shapes. For instance, the cushion part PP may include a polymer resin (for example, polyurethane, polycarbonate, polypropylene, and polyethylene) or a sponge molded by foaming rubber latex, a urethane-based material, or an acrylic-based material, although the present disclosure should not be limited thereto or thereby.

The cushion part PP may allow the body part HS to fit securely to the user, and thus, the user’s wearing comfort may be enhanced. The cushion part PP may be detachable from the body part HS. According to one or more embodiments, the cushion part PP may be omitted.

An optical system OL may be located in the main portion HS-1 of the body part HS. The optical system OL may magnify the images provided from the display modules DM. Each of the display modules DM may display the images in the third direction DR3 through the display area DA that is parallel to the first direction DR1 and the second direction DR2 crossing the first direction DR1. The optical system OL may be spaced apart from the display modules DM in the third direction DR3. The optical system OL may be placed between the display modules DM and the user’s eyes. The optical system OL may include a right-eye optical system OL_R and a left-eye optical system OL_L. The left-eye optical system OL_L may magnify and provide an image to the user’s left pupil, and the right-eye optical system OL_R may magnify and provide an image to the user’s right pupil.

The left-eye optical system OL_L and the right-eye optical system OL_R may be spaced apart from each other in the first direction DR1. A distance between the right-eye optical system OL_R and the left-eye optical system OL_L may be adjusted to correspond to a distance between the user’s eyes. In addition, a distance between the optical system OL and the display modules DM may be adjusted according to the user’s eyesight.

The optical system OL may be a convex aspherical lens. As an example, the optical system OL may be a pancake lens, but it should not be limited thereto or thereby. Each of the left-eye optical system OL_L and the right-eye optical system OL_R includes only one lens, although the present disclosure should not be limited thereto or thereby. For instance, each of the left-eye optical system OL_L and the right-eye optical system OL_R may include a plurality of lenses.

The electronic device ED-2 shown in FIGS. 4A and 4B may further include a window located on the display module DM. The window may include a base substrate, a reflection-reducing layer, and the like.

The display module DM included in the electronic devices ED-1 and ED-2 may have high-resolution characteristics. For example, the display module DM may have ultra-high resolution display quality of about 3000 ppi or higher.

FIG. 5 is a cross-sectional view of the display module according to one or more embodiments of the present disclosure. FIG. 5 is a cross-sectional view taken along the line I-I’ of FIG. 3B. Descriptions of FIG. 5 may be applied to the display module DM of FIG. 4B as well as the display module DM of FIG. 3B.

Referring to FIG. 5, the display module DM may include the display panel DP and an input-sensing panel ISP located on the display panel DP. The display panel DP may include a base layer BS, a circuit element layer CL, a light-emitting element layer EDL, and an encapsulation layer ECL.

The base layer BS may provide a base surface on which the circuit element layer CL is located. The base layer BS may be a rigid substrate, although the base layer BS should not be limited thereto or thereby. The base layer BS may be a flexible substrate.

The circuit element layer CL may be located on the base layer BS (as used herein, “located on” may mean “above”). The circuit element layer CL may include driving elements such as a transistor, signal lines, and signal pads. The light-emitting element layer EDL may include light-emitting elements arranged to overlap with the active area AA. The light-emitting elements of the light-emitting element layer EDL may be electrically connected to the driving elements of the circuit element layer CL and may emit light through the active area AA in response to a signal provided from the driving element.

The encapsulation layer ECL may be located on the light-emitting element layer EDL and may encapsulate the light-emitting elements. The encapsulation layer ECL may include a plurality of thin layers. The thin layers of the encapsulation layer ECL may improve an optical efficiency of the light-emitting elements or may protect the light-emitting elements.

The input-sensing panel ISP may be located on the display panel DP. The input-sensing panel ISP may sense the external input applied from the outside. The external input may be an input generated by the user. The input generated by the user may include various forms of external input, such as a part of the user's body, light, heat, a pen, or pressure.

The input-sensing panel ISP may be located on the display panel DP through a continuous process. The input-sensing panel ISP may be located directly on the display panel DP. In the present disclosure, the expression “the input-sensing panel ISP is located directly on the display panel DP” means that no other component is located between the input-sensing panel ISP and the display panel DP. That is, a separate adhesive member may not be located between the input-sensing panel ISP and the display panel DP.

In addition, the input-sensing panel ISP may be coupled to the display panel DP by an adhesive member. The adhesive member may include a conventional adhesive or pressure-sensitive adhesive.

According to one or more embodiments, the display module DM may not include the input-sensing panel ISP.

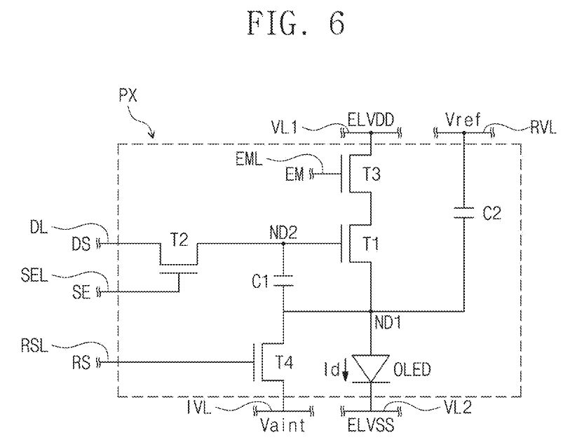

FIG. 6 is an equivalent circuit diagram of the pixel PX according to one or more embodiments of the present disclosure. FIG. 6 shows a pixel circuit of the pixel PX as an example.

Referring to FIG. 6, the pixel PX may include first, second, third, and fourth transistors T1, T2, T3, and T4, first and second capacitors C1 and C2, and a light-emitting element OLED. The first, second, third, and fourth transistors T1, T2, T3, and T4 are described as NMOS transistors, although the present disclosure should not be limited thereto or thereby. According to one or more embodiments, at least one of the first, second, third, or fourth transistors T1, T2, T3, or T4 may be a P-type transistor.

The first transistor T1 may be connected to the third transistor T3 for receiving the first driving voltage ELVDD. The first transistor may be referred to as a driving transistor. The first transistor T1 may include a first electrode connected to a first node ND1, a second electrode electrically connected to the third transistor T3, and a control electrode connected to a second node ND2.

The first transistor T1 may receive a data signal DS transmitted through a data line DL in response to a switching operation of the second transistor T2, and may provide a driving current Id to the light-emitting element OLED.

The second transistor T2 may be electrically connected between the data line DL and the second node ND2. The second transistor T2 may be referred to as a switching transistor. The second transistor T2 may include a first electrode connected to the second node ND2, a second electrode connected to the data line DL, and a control electrode connected to a first scan line SEL.

The second transistor T2 may be turned on in response to a write scan signal SE applied through the first scan line SEL, and may transmit the data signal DS, which is applied from the data line DL, to the control electrode of the first transistor T1.

The third transistor T3 may be electrically connected between a first power line VL1 and the first transistor T1. The third transistor T3 may include a first electrode connected to the second electrode of the first transistor T1, a second electrode connected to the first power line VL1, and a control electrode connected to a first emission control line EML. The third transistor T3 may be turned on in response to a first emission control signal EM applied through the first emission control line EML and may transmit the first driving voltage ELVDD, which is applied through the first power line VL1, to the first transistor T1.

The fourth transistor T4 may be electrically connected between an initialization voltage line IVL for receiving an initialization voltage Vaint and the first node ND1. The fourth transistor T4 may be referred to as an initialization transistor T4. The fourth transistor T4 may include a first electrode connected to the first node ND1, a second electrode connected to the initialization voltage line IVL, and a control electrode connected to a second scan line RSL. The fourth transistor T4 may be turned on in response to an initialization scan signal RS applied through the second scan line RSL and may transmit the initialization voltage Vaint, which is applied through the initialization voltage line IVL, to the first node ND1.

The light-emitting element OLED may be electrically connected between the first node ND1 and a second power line VL2 for receiving a second driving voltage ELVSS. The light-emitting element OLED may include a first electrode (anode) connected to the first node ND1 and a second electrode (cathode) connected to the second power line VL2.

The first capacitor C1 may be electrically connected between the first node ND1 and the second node ND2. The first capacitor C1 may include a first capacitor electrode connected to the first node ND1, and a second capacitor electrode connected to the second node ND2.

The second capacitor C2 may be electrically connected between a reference voltage line RVL and the first node ND1. The second capacitor C2 may include a first capacitor electrode connected to the reference voltage line RVL and a second capacitor electrode connected to the first node ND1.

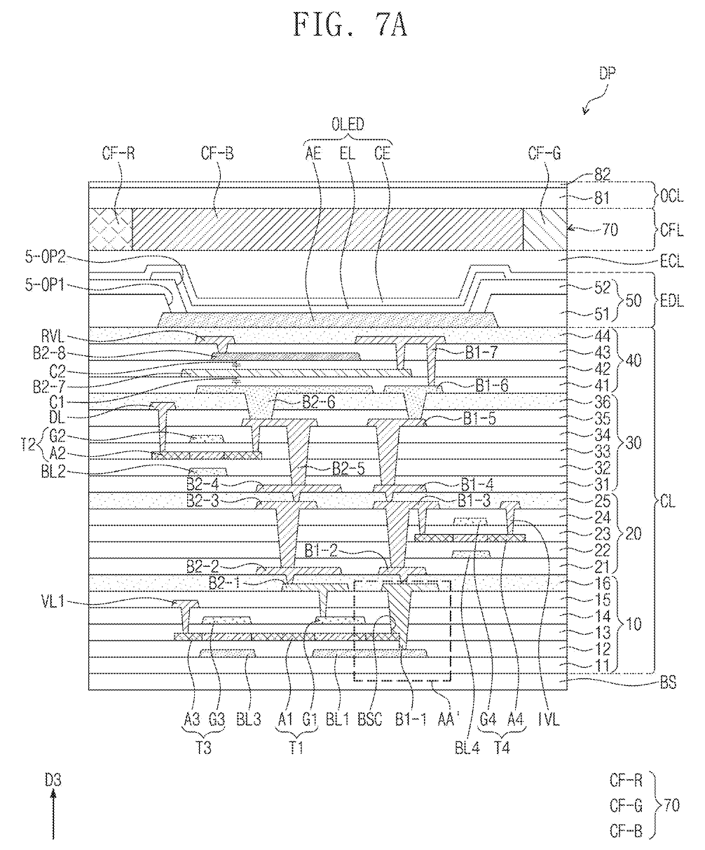

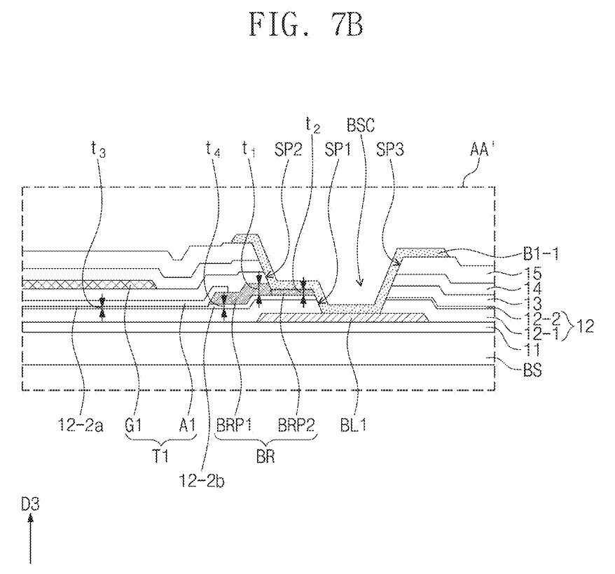

FIG. 7A is a cross-sectional view of the display panel DP according to one or more embodiments of the present disclosure.

Referring to FIG. 7A, the display panel DP may include the base layer BS, the circuit element layer CL, the light-emitting element layer EDL, and the encapsulation layer ECL. The display panel DP may further include a color filter layer CFL and/or an overcoat layer OCL.

The base layer BS may be a base layer on which other components of the display panel DP are stacked. The base layer BS may be a glass substrate, a metal substrate, or a polymer substrate. The base layer BS may be a rigid substrate or a flexible substrate that is bendable, foldable, or rollable.

The circuit element layer CL may be located on the base layer BS. The circuit element layer CL may include a plurality of insulating layers, a plurality of conductive patterns, and a plurality of connection patterns.

A first insulating layer 10 may be located on the base layer BS. The first insulating layer 10 may include first-first to first-sixth insulating layers 11 to 16 sequentially stacked on the base layer BS.

According to one or more embodiments, additional insulating layers may be located between the base layer BS and the first insulating layer 10, and driving transistors that drive the pixel PX (refer to FIG. 6) may be located between the additional insulating layers. The driving transistor may include a semiconductor pattern that is formed through a low-temperature polycrystalline silicon (LTPS) process and contains polysilicon (Poly-Si).

The first-first insulating layer 11 may be located on the base layer BS. The first-first, first-second, first-third, first-fourth, and first-fifth insulating layers 11, 12, 13, 14, and 15 may include one of silicon nitride and silicon oxide, or one insulating layer may include multiple inorganic layers, although the present disclosure should not be limited thereto or thereby. The multiple inorganic layers may have a structure in which a layer including silicon nitride and a layer including silicon oxide are alternately stacked with each other.

First and third conductive patterns BL1 and BL3 may be located on the first-first insulating layer 11. The first conductive pattern BL1 (e.g., the “conductive pattern,” in the claims) may overlap a first semiconductor pattern A1 of the first transistor T1, and the third conductive pattern BL3 may overlap a third semiconductor pattern A3 of the third transistor T3. The first and third conductive patterns BL1 and BL3 may block light incident to the first and third transistors T1 and T3. According to one or more embodiments, a constant voltage may be applied to at least one of the first or third conductive patterns BL1 or BL3.

The first and third conductive patterns BL1 and BL3 may include a metal material. The metal material may include one of molybdenum and titanium. According to one or more embodiments, the first and third conductive patterns BL1 and BL3 may include multiple metal layers. As an example, a lower layer of the multiple metal layers may include titanium, and an upper layer of the multiple metal layers may include molybdenum.

The first-second insulating layer 12 may be located on the first-first insulating layer 11, and may cover the first and third conductive patterns BL1 and BL3.

The first semiconductor pattern A1 of the first transistor T1 may be located on the first-second insulating layer 12. The first semiconductor pattern A1 may include one of indium gallium oxide (IGO) and indium gallium zinc oxide (IGZO).

The third semiconductor pattern A3 of the third transistor T3 may be located on the first-second insulating layer 12. The third semiconductor pattern A3 may include one of indium gallium oxide (IGO) and indium gallium zinc oxide (IGZO). The first semiconductor pattern A1 may be located at the same layer as the third semiconductor pattern A3, and the first and third semiconductor patterns A1 and A3 may be connected to each other.

The first-third insulating layer 13 may be located on the first-second insulating layer 12, and may cover the first and third semiconductor patterns A1 and A3.

A first gate G1 of the first transistor T1 may be located on the first-third insulating layer 13. The first gate G1 may overlap with the first semiconductor pattern A1. A third gate G3 of the third transistor T3 may be located on the first-third insulating layer 13. The third gate G3 may be overlap with the third semiconductor pattern A3.

The first and third gates G1 and G3 may include a metal material. The metal material may include one of molybdenum and titanium. According to one or more embodiments, the first and third gates G1 and G3 may include multiple metal layers. As an example, a lower layer may include titanium, and an upper layer may include molybdenum.

The first-fourth insulating layer 14 (e.g., the “fourth insulating layer,” in the claims) may be located on the first-third insulating layer 13, and may cover the first and third gates G1 and G3.

The first power line VL1 may be located on the first-fourth insulating layer 14. The first power line VL1 may correspond to the first power line described in FIG. 6. The first power line VL1 may be connected to one end of the third semiconductor pattern A3 via a contact hole defined through the first-third and first-fourth insulating layers 13 and 14. The first power line VL1 may include multiple metal layers. As an example, a lower layer may include titanium, an intermediate layer may include molybdenum, and an upper layer may include titanium.

The first-fifth insulating layer 15 may be located on the first-fourth insulating layer 14, and may cover the first power line VL1.

First-first and second-first connection patterns B1-1 and B2-1 may be located on the first-fifth insulating layer 15. The first-first connection pattern B1-1 (e.g., the “connection pattern,” in the claims) may be connected to the first conductive pattern BL1 and to the first semiconductor pattern A1 via a contact hole defined through the first-second to first-fifth insulating layers 12 to 15. At least a portion of the first-first connection pattern B1-1 may overlap with the first conductive pattern BL1 and the first semiconductor pattern A1.

The first-first and second-first connection patterns B1-1 and B2-1 may include multiple metal layers. As an example, a lower layer may include titanium, an intermediate layer may include molybdenum, and an upper layer may include titanium.

The first-first connection pattern B1-1 may be electrically connected to a second-seventh connection pattern B2-7, which constitutes an upper electrode of the first capacitor C1 and a lower electrode of the second capacitor C2.

According to the display panel DP, because the connection patterns, which connect the electrode forming the capacitor and the first semiconductor pattern A1, and the first conductive pattern BL1 are connected through one contact hole BSC, the number of the contact holes may be reduced, and the high-resolution display panel DP may be implemented. This will be described in detail later.

The second-first connection pattern B2-1 may be connected to the first gate G1 via a contact hole defined through the first-fourth and first-fifth insulating layers 14 and 15. At least a portion of the second-first connection pattern B2-1 may overlap with the first gate G1.

The first-sixth insulating layer 16 may be located on the first-fifth insulating layer 15, and may cover the first-first and second-first connection patterns B1-1 and B2-1.

First-second and second-second connection patterns B1-2 and B2-2 may be located on the first-sixth insulating layer 16. The first-second connection pattern B1-2 may be connected to the first-first connection pattern B1-1 via a contact hole defined through the first-sixth insulating layer 16. At least a portion of the first-second connection pattern B1-2 may overlap with the first-first connection pattern B1-1.

The second-second connection pattern B2-2 may be connected to the second-first connection pattern B2-1 via a contact hole defined through the first-sixth insulating layer 16. At least a portion of the second-second connection pattern B2-2 may overlap with the second-first connection pattern B2-1.

The second insulating layer 20 may be located on the first insulating layer 10. The second insulating layer 20 may include second-first, second-second, second-third, second-fourth, and second-fifth insulating layers 21, 22, 23, 24, and 25 sequentially stacked on the first insulating layer 10. According to one or more embodiments, one of the second-first to second-fifth insulating layers 21 to 25 may be omitted, and the second insulating layer 20 may further include an additional insulating layer.

The second-first to second-fourth insulating layers 21 to 24 may include one of silicon nitride and silicon oxide, or one insulating layer may include multiple inorganic layers, although the present disclosure should not be limited thereto or thereby. The multiple inorganic layers may have a structure in which a layer including silicon nitride and a layer including silicon oxide are alternately stacked with each other.

The second-first insulating layer 21 may be located on the first-sixth insulating layer 16, and may cover the first-second and second-second connection patterns B1-2 and B2-2.

A fourth conductive pattern BL4 may be located on the second-first insulating layer 21. The fourth conductive pattern BL4 may overlap with a fourth semiconductor pattern A4 of the fourth transistor T4. The fourth conductive pattern BL4 may block light incident to the fourth transistor T4.

The fourth conductive pattern BL4 may include a metal material. The metal material may include one of molybdenum and titanium. According to one or more embodiments, the fourth conductive pattern BL4 may include multiple metal layers. As an example, a lower layer may include titanium, and an upper layer may include molybdenum.

The second-second insulating layer 22 may be located on the second-first insulating layer 21, and may cover the fourth conductive pattern BL4.

The fourth semiconductor pattern A4 of the fourth transistor T4 may be located on the second-second insulating layer 22. The fourth semiconductor pattern A4 may include one of indium gallium oxide (IGO) and indium gallium zinc oxide (IGZO).

The second-third insulating layer 23 may be located on the second-second insulating layer 22, and may cover the fourth semiconductor pattern A4.

A fourth gate G4 of the fourth transistor T4 may be located on the second-third insulating layer 23. The fourth gate G4 may overlap with the fourth semiconductor pattern A4.

The fourth gate G4 may include a metal material. The metal material may include one of molybdenum and titanium. According to one or more embodiments, the fourth gate G4 may include multiple metal layers. As an example, a lower layer may include titanium, and an upper layer may include molybdenum.

The second-fourth insulating layer 24 may be located on the second-third insulating layer 23, and may cover the fourth gate G4.

The initialization voltage line IVL and first-third and second-third connection patterns B1-3 and B2-3 may be located on the second-fourth insulating layer 24. One end of the first-third connection pattern B1-3 may be connected to one side of the fourth semiconductor pattern A4 via a contact hole defined through the second-third and second-fourth insulating layers 23 and 24, and the other end of the first-third connection pattern B1-3 may be connected to the first-second connection pattern B1- 2 via a contact hole defined through the second-first to second-fourth insulating layers 21 to 24.

The initialization voltage line IVL may be connected to the other side of the fourth semiconductor pattern A4 via a contact hole defined through the second-third and second-fourth insulating layers 23 and 24.

The second-third connection pattern B2-3 may be connected to the second-second connection pattern B2-2 via a contact hole defined through the second-first to second-fourth insulating layers 21 to 24.

The second-fifth insulating layer 25 may be located on the second-fourth insulating layer 24, and may cover the initialization voltage line IVL and the first-third and second-third connection patterns B1-3 and B2-3.

First-fourth and second-fourth connection patterns B1-4 and B2-4 may be located on the second-fifth insulating layer 25. The first-fourth connection pattern B1-4 may be connected to the first-third connection pattern B1-3 via a contact hole defined through the second-fifth insulating layer 25. The second-fourth connection pattern B2-4 may be connected to the second-third connection pattern B2-3 via a contact hole defined through the second-fifth insulating layer 25.

The first-fourth and second-fourth connection patterns B1-4 and B2-4 may include multiple metal layers. As an example, a lower layer may include titanium, an intermediate layer may include molybdenum, and an upper layer may include titanium.

The third insulating layer 30 may be located on the second insulating layer 20. The third insulating layer 30 may include third-first, third-second, third-third, third-fourth, third-fifth, and third-sixth insulating layers 31 to 36 sequentially stacked on the second insulating layer 20. According to one or more embodiments, one of the third-first to third-sixth insulating layers 31 to 36 may be omitted, and the third insulating layer 30 may further include an additional insulating layer.

The third-first to third-fifth insulating layers 31 to 35 may include one of silicon nitride and silicon oxide, or one insulating layer may include multiple inorganic layers, although the present disclosure should not be limited thereto or thereby. The multiple inorganic layers may have a structure in which a layer including silicon nitride and a layer including silicon oxide are alternately stacked with each other.

The third-first insulating layer 31 may be located on the second-fifth insulating layer 25 and may cover the first-fourth and second-fourth connection patterns B1-4 and B2-4.

A second conductive pattern BL2 may be located on the third-first insulating layer 31. The second conductive pattern BL2 may overlap a second semiconductor pattern A2 of the second transistor T2. The second conductive pattern BL2 may block light incident to the second transistor T2.

The second conductive pattern BL2 may include a metal material. The metal material may include one of molybdenum and titanium. According to one or more embodiments, the second conductive pattern BL2 may include multiple metal layers. As an example, a lower layer may include titanium, and an upper layer may include molybdenum.

The third-second insulating layer 32 may be located on the third-first insulating layer 31 and may cover the second conductive pattern BL2.

The second semiconductor pattern A2 of the second transistor T2 may be located on the third-second insulating layer 32. The second semiconductor pattern A2 may include one of indium gallium oxide (IGO) and indium gallium zinc oxide (IGZO).

The third-third insulating layer 33 may be located on the third-second insulating layer 32 and may cover the second semiconductor pattern A2.

A second gate G2 of the second transistor T2 may be located on the third-third insulating layer 33. The second gate G2 may overlap the second semiconductor pattern A2.

The second gate G2 may include a metal material. The metal material may include one of molybdenum and titanium. According to one or more embodiments, the second gate G2 may include multiple metal layers. As an example, a lower layer may include titanium, and an upper layer may include molybdenum.

The third-fourth insulating layer 34 may be located on the third-third insulating layer 33 and may cover the second gate G2.

First-fifth and second-fifth connection patterns B1-5 and B2-5 may be located on the third-fourth insulating layer 34. The first-fifth connection pattern B1-5 may be connected to the first-fourth connection pattern B1-4 via a contact hole defined through the third-first to third-fourth insulating layers 31 to 34. At least a portion of the first-fifth connection pattern B1-5 may overlap with the first-fourth connection pattern B1-4.

One end of the second-fifth connection pattern B2-5 may be connected to the second-fourth connection pattern B2-4 via a contact hole defined through the third-first to third-fourth insulating layers 31 to 34. The other end of the second-fifth connection pattern B2-5 may be connected to one side of the second semiconductor pattern A2 via a contact hole defined through the third-third and third-fourth insulating layers 33 and 34.

The first-fifth and second-fifth connection patterns B1-5 and B2-5 may include multiple metal layers. As an example, a lower layer may include titanium, an intermediate layer may include molybdenum, and an upper layer may include titanium.

The third-fifth insulating layer 35 may be located on the third-fourth insulating layer 34, and may cover the first-fifth and second-fifth connection patterns B1-5 and B2-5.

The data line DL may be located on the third-fifth insulating layer 35. The data line DL may be connected to the other side of the second semiconductor pattern A2 via a contact hole defined through the third-third to third-fifth insulating layers 33 to 35. The data line DL may include multiple metal layers. As an example, a lower layer may include titanium, an intermediate layer may include molybdenum, and an upper layer may include titanium.

The third-sixth insulating layer 36 may be located on the third-fifth insulating layer 35 and may cover the data line DL.

First-sixth and second-sixth connection patterns B1-6 and B2-6 may be located on the third-sixth insulating layer 36. The first-sixth connection pattern B1-6 may be connected to the first-fifth connection pattern B1-5 via a contact hole defined through the third-fifth and third-sixth insulating layers 35 and 36. At least a portion of the first-sixth connection pattern B1-6 may overlap the first-fifth connection pattern B1-5.

The second-sixth connection pattern B2-6 may be connected to the second-fifth connection pattern B2-5 via a contact hole defined through the third-fifth and third-sixth insulating layers 35 and 36. At least a portion of the second-sixth connection pattern B2-6 may overlap the second-fifth connection pattern B2-5.

The first-sixth and second-sixth connection patterns B1-6 and B2-6 may include multiple metal layers. As an example, a lower layer may include titanium, an intermediate layer may include molybdenum, and an upper layer may include titanium.

The fourth insulating layer 40 may be located on the third insulating layer 30. The fourth insulating layer 40 may include fourth-first, fourth-second, fourth-third, and fourth-fourth insulating layers 41, 42, 43, and 44 sequentially stacked on the third insulating layer 30. According to one or more embodiments, at least one of the fourth-first to fourth-fourth insulating layers 41 to 44 may be omitted, and the fourth insulating layer 40 may further include an additional insulating layer.

The fourth-first to fourth-fourth insulating layers 41 to 44 may include one of silicon nitride and silicon oxide, or one insulating layer may include multiple inorganic layers, although the present disclosure should not be limited thereto or thereby. The multiple inorganic layers may have a structure in which a layer including silicon nitride and a layer including silicon oxide are alternately stacked with each other.

The second-seventh connection pattern B2-7 may be located on the fourth-first insulating layer 41. The second-seventh connection pattern B2-7 may function as the upper electrode of the first capacitor C1 and may also function as the lower electrode of the second capacitor C2 as described with reference to FIG. 6.

When the second-seventh connection pattern B2-7 serves as the upper electrode of the first capacitor C1, the second-sixth connection pattern B2-6 may serve as a lower electrode of the first capacitor C1.

When the second-seventh connection pattern B2-7 serves as the lower electrode of the second capacitor C2, a second-eighth connection pattern B2-8 described later may serve as an upper electrode of the second capacitor C2.

The second-seventh connection pattern B2-7 may include multiple metal layers. As an example, a lower layer may include titanium, an intermediate layer may include molybdenum, and an upper layer may include titanium.

The fourth-second insulating layer 42 may be located on the fourth-first insulating layer 41 and may cover the second-seventh connection pattern B2-7.

The second-eighth connection pattern B2-8 may be located on the fourth-second insulating layer 42. The second-eighth connection pattern B2-8 may function as the upper electrode of the second capacitor C2 described with reference to FIG. 6

The second-eighth connection pattern B2-8 may include multiple metal layers. As an example, a lower layer may include titanium, an intermediate layer may include molybdenum, and an upper layer may include titanium.

The fourth-third insulating layer 43 may be located on the fourth-second insulating layer 42 and may cover the second-eighth connection pattern B2-8.

The reference voltage line RVL and a first-seventh connection pattern B1-7 may be located on the fourth-third insulating layer 43.

The reference voltage line RVL may be connected to the second-eighth connection pattern B2-8 via a contact hole defined through the fourth-third insulating layer 43.

One end of the first-seventh connection pattern B1-7 may be connected to the second-seventh connection pattern B2-7 via a contact hole defined through the fourth-second and fourth-third insulating layers 42 and 43, and the other end of the first-seventh connection pattern B1-7 may be connected to the first-sixth connection pattern B1-6 via a contact hole defined through the fourth-first to fourth-third insulating layers 41 to 43.

The reference voltage line RVL and the first-seventh connection pattern B1-7 may include multiple metal layers. As an example, a lower layer may include titanium, an intermediate layer may include molybdenum, and an upper layer may include titanium.

However, the stacked structure of the display panel DP should not be limited thereto or thereby, and the second semiconductor pattern A2 of the second transistor T2 may be located at the same layer as the fourth semiconductor pattern A4 of the fourth transistor T4. In this case, the first and third semiconductor patterns A1 and A3 may be located under or on the second and fourth semiconductor patterns A2 and A4, but should not be particularly limited.

The first semiconductor pattern A1 may be connected to the second-seventh connection pattern B2-7 that serves as the electrode of the capacitor through the first-first, first-second, first-third, first-fourth, first-fifth, first-sixth, and first-seventh connection patterns B1-1, B1-2, B1-3, B1-4, B1-5, B1-6, and B1-7 connected to the first conductive pattern BL1.

In the process of forming the contact hole BSC for placing the first-first connection pattern B1-1, if the first semiconductor pattern A1 is exposed through the contact hole BSC when etching the insulating layers including the inorganic material, the first semiconductor pattern A1 may be concurrently or substantially simultaneously removed together with the insulating layers. When the first semiconductor pattern A1 is concurrently or substantially simultaneously removed together with the insulating layers, a contact area between the first semiconductor pattern A1 and the first-first connection pattern B1-1 decreases, and thus, a resistance increases. In addition, the inorganic layers located under the first semiconductor pattern A1 may be partially removed, and as a result, cracks may occur in the first-first connection pattern B1-1.

Accordingly, a technology is suitable to improve a contact reliability between the first semiconductor pattern A1 and the first-first connection pattern B1-1 by reducing or preventing defects that may arise from the removal of the first semiconductor pattern A1 during the process of forming the contact hole for placing the first-first connection pattern B1-1.

The fourth-fourth insulating layer 44 may be located on the fourth-third insulating layer 43, and may cover the reference voltage line RVL and the first-seventh connection pattern B1-7.

The light-emitting element layer EDL may be located on the circuit element layer CL. The light-emitting element layer EDL may include the light-emitting element OLED and a pixel definition layer 50.

The pixel definition layer 50 may be located on the fourth insulating layer 40. The pixel definition layer 50 may include a first layer 51 and a second layer 52. A first display opening 5-OP1 may be defined through the first layer 51 to expose at least a portion of the first electrode AE of the light-emitting element OLED. A second display opening 5-OP2 may be defined through the second layer 52 to overlap the first display opening 5-OP1. The second display opening 5-OP2 may have a width greater than a width of the first display opening 5-OP1.

The first layer 51 may include an organic material. As an example, the first layer 51 may include polyimide. The second layer 52 may include an inorganic material. As an example, the second layer 52 may include one of silicon nitride and silicon oxide, or one insulating layer may include multiple inorganic layers, although the present disclosure should not be limited thereto or thereby.

The multiple inorganic layers may have a structure in which a lower layer including silicon oxide, an intermediate layer including silicon nitride, and an upper layer including silicon oxide are alternately stacked with each other.

The light-emitting element OLED may include the first electrode AE, a light-emitting layer EL, and the second electrode CE. The first electrode AE may include a transparent conductive oxide and a metal material. According to one or more embodiments, the first electrode AE may include a lower layer including indium tin oxide (ITO), an intermediate layer including Ag, and an upper layer including indium tin oxide (ITO).

According to one or more embodiments, the light-emitting element OLED may further include at least one of a hole control layer located between the first electrode AE and the light-emitting layer EL or an electron control layer located between the light-emitting layer EL and the second electrode CE.

The second electrode CE may be commonly located in the pixels PX. The second electrode CE may include an alloy. For example, the second electrode CE may include a magnesium-lithium (Mg-Li) alloy. According to one or more embodiments, the light-emitting element OLED may further include a protective layer located on the second electrode CE.

The encapsulation layer ECL may be located on the light-emitting element layer EDL. The encapsulation layer ECL may include a plurality of layers. As an example, the encapsulation layer ECL may include a first inorganic layer, an organic layer, and a second inorganic layer. The first and second inorganic layers may include an inorganic material and may protect the pixels from moisture and oxygen. The organic layer may include an organic material and may protect the light-emitting element OLED from a foreign substance such as dust particles.

The color filter layer CFL may be located on the encapsulation layer ECL. The color filter layer CFL may include first, second, and third color filters CF-R, CF-B, and CF-G. Each of the first, second, and third color filters CF-R, CF-B, and CF-G may transmit light within a specific wavelength range and may block light outside the specific wavelength range. Therefore, the first, second, and third color filters CF-R, CF-B, and CF-G may absorb light leaked into adjacent light-emitting areas. Each of first, second, and third color filters CF-R, CF-B, and CF-G may include a base resin and a dye and/or a pigment dispersed in the base resin. The base resin may be a medium in which the dye and/or the pigment are dispersed and may include various resin compositions that are generally referred to as a binder.

FIG. 7A shows the second color filter CF-B located on the light-emitting element OLED emitting a blue light. The first color filter CF-R may transmit a red light, the second color filter CF-B may transmit the blue light, and the third color filter CF-G may transmit a green light. According to one or more embodiments, the first, second, and third color filters CF-R, CF-B, and CF-G may have a stacked structure on the pixel definition layer 50. The stacked structure of the first, second, and third color filters CF-R, CF-B, and CF-G may function as a light-shielding pattern that reduces or prevents color mixing between adjacent light-emitting areas.

The overcoat layer OCL may be located on the color filter layer CFL. The overcoat layer OCL may cover the color filter layer CFL. The overcoat layer OCL may include a first cover layer 81 and a second cover layer 82 located on the first cover layer 81.

The first cover layer 81 may include an organic material. Accordingly, the first cover layer 81 may provide a flat upper surface. The second cover layer 82 may cover the upper surface of the first cover layer 81. The second cover layer 82 may include an inorganic material. As an example, the second cover layer 82 may include silicon nitride.

According to one or more embodiments, one of the color filter layer CFL and the overcoat layer OCL may be omitted.

FIG. 7B is an enlarged cross-sectional view of an area AA’ of FIG. 7A. FIG. 7B is an enlarged view showing an area where the first conductive pattern BL1 is electrically connected to the first semiconductor pattern A1 via the first-first connection pattern B1-1.

Referring to FIG. 7B, the display panel DP may include the base layer BS, the insulating layers 11 to 15 located on the base layer BS, the first conductive pattern BL1, the first transistor T1 including the first semiconductor pattern A1 and the first gate G1, and the first-first connection pattern B1-1 electrically connecting the first conductive pattern BL1 and the first semiconductor pattern A1.

The first-first insulating layer 11 may be located on the base layer BS (as used herein, “located on” may mean “above”). The first conductive pattern BL1 may be located on the first-first insulating layer 11. The first-second insulating layer 12 may be located on the first-first insulating layer 11 and may cover a portion of the first conductive pattern BL1. The first semiconductor pattern A1 may be located on the first-second insulating layer 12.

The first-second insulating layer 12 may include a plurality of inorganic layers. The first-second insulating layer 12 may include a first inorganic layer 12-1 (e.g., the “first insulating layer,” in the claims) located on the first-first insulating layer 11 and a second inorganic layer 12-2 (e.g., the “second insulating layer,” in the claims) located on the first inorganic layer 12-1. The first inorganic layer 12-1 may include silicon nitride, and the second inorganic layer 12-2 may include silicon oxide. The first inorganic layer 12-1 may have a thickness that is greater than a thickness of the second inorganic layer 12-2. The first inorganic layer 12-1 may be an insulating layer to reduce or prevent impurities in the lower layer diffusing into the upper layer. The second inorganic layer 12-2 may be an insulating layer to secure device characteristics of the first semiconductor pattern A1.

The second inorganic layer 12-2 may include a first insulation portion 12-2a and a second insulation portion 12-2b. The first insulation portion 12-2a may be defined as a portion that does not overlap with a bridge pattern BR described later (e.g., a portion that is separated from the bridge pattern BR in plan view). The second insulation portion 12-2b may be defined as a portion that overlaps with the bridge pattern BR. The first insulation portion 12-2a may have a thickness that is less than a thickness of the second insulation portion 12-2b. In a process of forming the bridge pattern BR described later, a portion that is not covered by the bridge pattern BR may be partially etched and may be formed as the first insulation portion 12-2a having the thickness that is less than that of a portion (e.g., the second insulation portion 12-2b) that is not etched.

The first-third insulating layer 13 (e.g., the “third insulating layer,” in the claims) may be located on the first-second insulating layer 12, and may cover the first semiconductor pattern A1. The first gate G1 may overlap with the first semiconductor pattern A1 and may be located on the first-third insulating layer 13. The first-fourth insulating layer 14 may be located on the first-third insulating layer 13 and may cover the first gate G1. The first-fifth insulating layer 15 may be located on the first-fourth insulating layer 14.

The display panel DP may further include the bridge pattern BR to connect the first-first connection pattern B1-1 and the first semiconductor pattern A1. The bridge pattern BR may be located between the first-second insulating layer 12 and the first-third insulating layer 13. In detail, the bridge pattern BR may be located between the second inorganic layer 12-2 and the first semiconductor pattern A1. The first semiconductor pattern A1 may cover at least a portion of the bridge pattern BR. A portion of the bridge pattern BR, which is not covered by the first semiconductor pattern A1, may be covered by the first-third insulating layer 13 and the first-first connection pattern B1-1.

The bridge pattern BR may include a first bridge portion BRP1 and a second bridge portion BRP2. The first bridge portion BRP1 may be defined as a portion covered by the first-third insulating layer 13, and the second bridge portion BRP2 may be defined as a portion exposed without being covered by the first-third insulating layer 13. The first bridge portion BRP1 may have a thickness that is greater than a thickness of the second bridge portion BRP2. The exposed portion of the bridge pattern BR not covered by the first-third insulating layer 13 (e.g., the second bridge portion BRP2) may be partially etched during a process of forming the contact hole BSC to be described later, and thus, the exposed and etched portion may be formed as the second bridge portion BRP2 with a thickness that is less than the unetched portion

Because the display panel DP according to the present disclosure includes the bridge pattern BR containing molybdenum (Mo) or titanium (Ti), the first-first connection pattern B1-1 and the bridge pattern BR may be in contact over a large area, and the bridge pattern BR and the first semiconductor pattern AR may overlap a large area while keeping a thickness of the first semiconductor pattern A1 thin. Thus, a contact resistance may be reduced and a stable current flow may be secured.

The thickness of the first bridge portion BRP1 may be greater than the thickness of the first semiconductor pattern A1. Because the bridge pattern BR for contacting the first-first connection pattern BR is formed to be sufficiently thick, the bridge pattern BR may remain without being entirely etched away during the process of forming the contact hole BSC. In the process of forming the contact hole BSC to be described later, the exposed portion of the bridge pattern BR may be etched during the etching of the first-second insulating layer 12, causing its thickness to be reduced. Even when the exposed portion of the bridge pattern BR is etched, a corresponding thickness of the bridge pattern BR may suitably remain to allow for stable contact with the first-first connection pattern B1-1 over a sufficient area.

Unlike the present disclosure, in a case without the bridge pattern BR, the first semiconductor pattern A1 may suitably have a structure where it is exposed through the contact hole BSC to contact the first-first connection pattern B1-1. In this case, during a dry-etching process to form the contact hole BSC, the first semiconductor pattern A1 is exposed before the first conductive pattern BL1. In a case where the dry-etching process continues in order to expose the first conductive pattern BL1 after the first semiconductor pattern A1 is exposed, the exposed first semiconductor pattern A1 may also be etched and removed. In detail, the conditions for effectively etching the first inorganic layer 12-1, which includes silicon nitride and is located at a bottom the contact hole BSC, may not have a high selectivity with respect to the first semiconductor pattern A1, which includes an oxide semiconductor material, and the etch amount of the exposed first semiconductor pattern A1 may be large. This means that the exposed first semiconductor pattern A1 may be entirely etched away, and the insulating layers located under the first semiconductor pattern A1 may be exposed. On the other hand, to reduce or prevent the likelihood of the exposed first semiconductor pattern A1 being completely etched to thereby leave a remaining portion, the first semiconductor pattern A1 may suitably have a greater thickness. However, when the thickness of the first semiconductor pattern A1 increases, it is difficult to secure desired characteristics of an oxide semiconductor.

The bridge pattern BR may be spaced apart from the first semiconductor pattern A1. The bridge pattern BR may contact the first-first connection pattern B1-1 and the first semiconductor pattern A1, and the first-first connection pattern B1-1 may contact the first conductive pattern BL1. Accordingly, the first conductive pattern BL1 may be electrically connected to the first semiconductor pattern A1 via the first-first connection pattern B1-1 and the bridge pattern BR.

The bridge pattern BR may have a single-layer or multi-layer structure. The bridge pattern BR may include a metal material that has a high selectivity with respect to etching conditions to etch a silicon nitride layer and is easy to form with a thick thickness. For example, the bridge pattern BR may include molybdenum (Mo) or titanium (Ti).

The display panel DP may further include (e.g., may define) the contact hole BSC penetrating through the first-second to first-fifth insulating layers 12 to 15. A portion of the first conductive pattern BL1 and a portion of the bridge pattern BR may be exposed through the contact hole BSC. Side surfaces of the first-second to first-fifth insulating layers 12 to 15 may be exposed through the contact hole BSC.

The contact hole BSC may include a first side portion SP1, a second side portion SP2, and a third side portion SP3. The first side portion SP1 may correspond to a side surface of the exposed second bridge portion BRP2 and to a side surface of the exposed first-second insulating layer 12 located below the second bridge portion BRP2. The second side portion SP2 may correspond to a side surface of the exposed first bridge portion BRP1 and to the side surfaces of the exposed first-third to first-fifth insulating layers 13, 14, and 15 located above the first bridge portion BRP1. The third side portion SP3 may correspond to side surfaces of the first-second to first-fifth insulating layers 12 to 15 where the bridge pattern BR is not located.

The contact hole BSC may be spaced apart from the first semiconductor pattern A1. That is, the first semiconductor pattern A1 may not be exposed through the contact hole BSC and may be covered by the first-third insulating layer 13.

The first-first connection pattern B1-1 may be located in the contact hole BSC. A portion of the first conductive pattern BL1 and a portion of the bridge pattern BR, which are exposed through the contact hole BSC, may contact the first-first connection pattern B1-1. The side surfaces of the first-second to first-fifth insulating layers 12 to 15, which are exposed through the contact hole BSC, may contact the first-first connection pattern B1-1. The first-first connection pattern B1-1 may cover the exposed upper surface of the first conductive pattern BL1, the exposed upper and side surfaces of the bridge pattern BR, and the exposed side surfaces of the first-second to first-fifth insulating layers 12 to 15.

Because the display panel DP includes the bridge pattern BR, a sufficient contact area with the first-first connection pattern B1-1 may be secured, and the occurrence of cracks at the contact surface may be reduced or prevented. Accordingly, the contact resistance between the first-first connection pattern B1-1 and the first semiconductor pattern A1 may be reduced. In detail, according to the display panel DP of the present disclosure, because the contact area between the first conductive pattern BL1 and the first-first connection pattern B1-1, the contact area between the first-first connection pattern B1-1 and the bridge pattern BR, and the contact area between the bridge pattern BR and the first semiconductor pattern A1 are sufficient, the stable current flow between the first conductive pattern BL1 and the first semiconductor pattern A1 may be secured even without forming the first semiconductor pattern A1 with a greater thickness.

Unlike the present disclosure, when the display panel DP does not include the bridge pattern BR, a structure where the first semiconductor pattern A1, instead of the bridge pattern BR, is exposed through the contact hole BSC and contacts the first-first connection pattern B1-1 is implemented. However, the first semiconductor pattern A1 may be etched together with the first inorganic layer 12-1 during the process of forming the contact hole BSC to expose the first conductive pattern BL1. This is because the conditions for effectively etching silicon nitride, which is located relatively at the bottom with respect to the contact hole BSC, may have a low selectivity with respect to the first semiconductor pattern A1 containing oxide such as IGO or IGZO. As the first semiconductor pattern A1 is etched together with the first inorganic layer 12-1, only the portion of the first semiconductor pattern A1, which is covered by the first-third insulating layer 13, remains. Then, when the first-first connection pattern B1-1 is formed in the contact hole BSC, the first-first connection pattern B1-1 may be in contact only with the side surface of the first semiconductor pattern A1. Therefore, an increase in the contact resistance and the occurrence of current crowding due to the reduced contact area may occur. Further, a portion of the first-second insulating layer 12 located under the first semiconductor pattern A1 may also be etched, and cracks due to defects at the contact surface may occur.

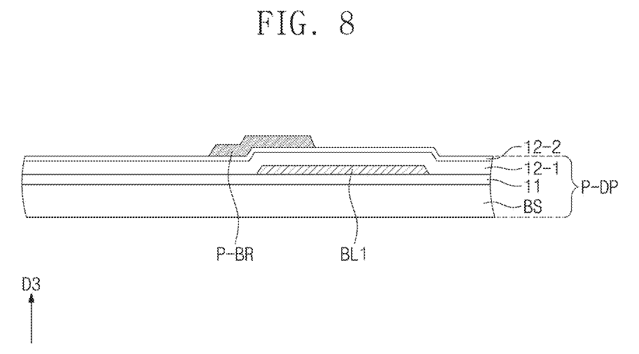

FIGS. 8 to 14 are cross-sectional views showing processes of a manufacturing method of the display panel according to one or more embodiments of the present disclosure.

FIGS. 8 to 14 are cross-sectional views showing the processes of the manufacturing method of the display panel in an area corresponding to FIG. 7B according to one or more embodiments of the present disclosure. In FIGS. 8 to 14, the same/similar reference numerals denote the same/similar elements in FIG. 7B, and thus, detailed descriptions of the same/similar elements will be omitted.

The manufacturing method of the display panel may include forming a preliminary bridge pattern B-PR on a preliminary display panel P-DP, forming the first semiconductor pattern A1 including the oxide semiconductor, forming the first-third insulating layer 13, forming the first gate G1, forming the first-fourth insulating layer 14, forming a preliminary contact hole P-BSC, and forming the contact hole BSC. The manufacturing method of the display panel may further include forming the first-fifth insulating layer 15. In addition, the manufacturing method of the display panel may further include forming the first-first connection pattern B1-1.

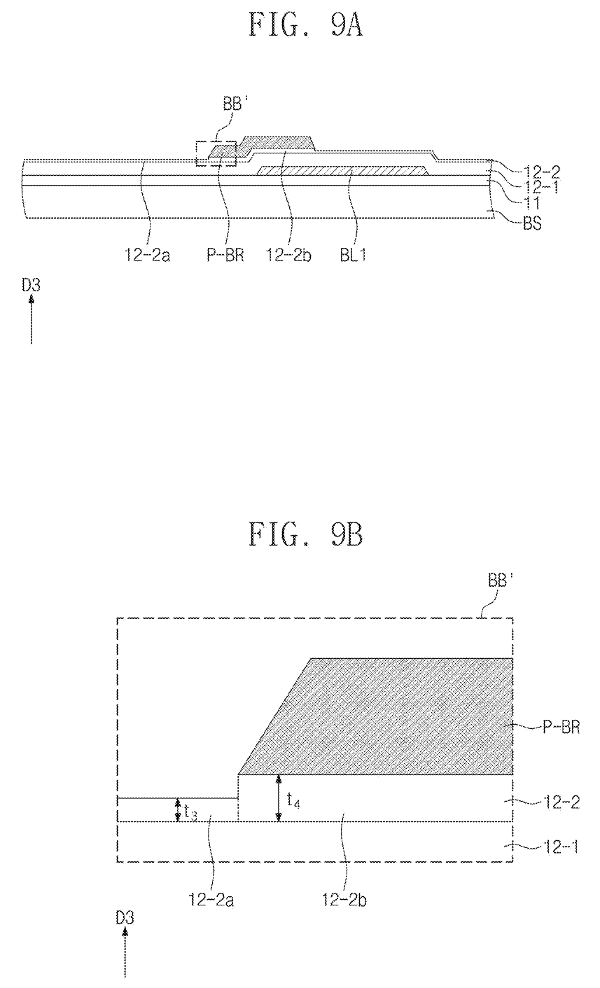

FIGS. 8 and 9A schematically show the forming of the preliminary bridge pattern P-BR on the preliminary display panel P-DP. FIG. 9B is an enlarged cross-sectional view of an area BB’ shown in FIG. 9A.

Referring to FIG. 8, the preliminary display panel P-DP may include the base layer BS, the first conductive pattern BL1 located on the base layer BS, the first inorganic layer 12-1 located on the first conductive pattern BL1, and the second inorganic layer 12-2 located on the first inorganic layer 12-1.

The first inorganic layer 12-1 may include silicon nitride, and the second inorganic layer 12-2 may include silicon oxide. The thickness of the first inorganic layer 12-1 may be greater than the thickness of the second inorganic layer 12-2. As an example, the thickness of the first inorganic layer 12-1 may be within a range from about 1500Å to about 2000Å. The thickness of the second inorganic layer 12-2 may be within a range from about 300Å to about 700Å.

The preliminary display panel P-DP may further include the first-first insulating layer 11 located between the base layer BS and the first conductive pattern BL1.

The preliminary bridge pattern P-BR may be formed on the preliminary display panel D-DP. The forming of the preliminary bridge pattern P-BR may include depositing a bridge metal layer on the second inorganic layer 12-2, dry-etching the bridge metal layer to pattern the bridge metal layer, and cleaning the patterned bridge metal layer.

The preliminary bridge pattern P-BR may be formed by depositing the bridge metal layer on the second inorganic layer 12-2, forming a photoresist pattern on a portion of the bridge metal layer, and dry-etching the bridge metal layer. The preliminary bridge pattern P-BR may have a single-layer or multi-layer structure. The preliminary bridge pattern P-BR may include a metal that has high selectivity with respect to etching conditions for etching the silicon nitride layer and is easy to deposit to a greater thickness. For example, the preliminary bridge pattern P-BR may include molybdenum (Mo) or titanium (Ti). FIG. 8 shows the preliminary bridge pattern P-BR in a patterned state on the preliminary display panel P-DP.

Then, a cleaning process may be performed to remove contaminants, such as fluorine or chlorine, from the dry-etching. In detail, a hydrofluoric (HF) cleaning process may be performed. For example, a BOE (Buffered Oxide Etch) cleaning process may be performed. In the case of HF cleaning, the exposed portion of the second inorganic layer 12-2, which is not covered by the preliminary bridge pattern P-BR, may be partially etched. FIG. 9A shows a state where a step difference is formed in the second inorganic layer 12-2 after the HF cleaning process. Because the preliminary bridge pattern P-BR contains molybdenum (Mo) or titanium (Ti), the preliminary bridge pattern P-BR may have high selectivity with respect to the HF cleaning process and may remain without being etched.

Referring to FIGS. 9A and 9B, the second inorganic layer 12-2 may be divided into the first insulation portion 12-2a and the second insulation portion 12-2b by the HF cleaning process. The first insulation portion 12-2a may be defined as the portion that does not overlap with the bridge pattern BR to be described later, and the second insulation portion 12-2b may be defined as the portion that overlaps with the bridge pattern BR to be described later. The first insulation portion 12-2a may have a thickness t₃ that is less than a thickness t₄ of the second insulation portion 12-2b.

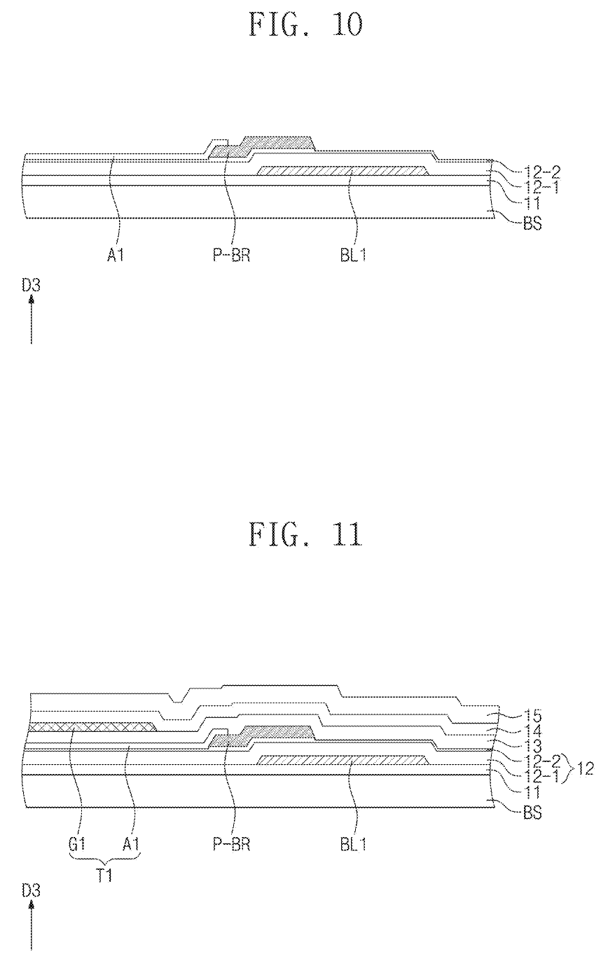

FIG. 10 is a schematic diagram showing the forming of the first semiconductor pattern A1.

Referring to FIG. 10, the first semiconductor pattern A1 may include the oxide semiconductor. As an example, the first semiconductor pattern A1 may include indium gallium oxide (IGO) or indium gallium zinc oxide (IGZO).

The first semiconductor pattern A1 may be formed by depositing the oxide semiconductor layer on the second inorganic layer 12-2 and the preliminary bridge pattern P-BR, and patterning the oxide semiconductor layer through a photolithography process. As an example, a portion of the oxide semiconductor layer that does not overlap a photoresist pattern may be removed through a wet-etching process using the photoresist pattern as a mask.

The first semiconductor pattern A1 may be formed to allow at least a portion thereof to overlap with the preliminary bridge pattern P-BR. Accordingly, the first semiconductor pattern A1 may contact and may be electrically connected to the preliminary bridge pattern P-BR.

FIG. 11 is a schematic diagram showing the forming of the first-third insulating layer 13, the forming of the first gate G1, the forming of the first-fourth insulating layer 14, and the forming of the first-fifth insulating layer 15.

Referring to FIG. 11, the first-third insulating layer 13 may be formed on the second inorganic layer 12-2. The first-third insulating layer 13 may be formed to cover the preliminary bridge pattern P-BR and the first semiconductor pattern A1. The first gate G1 may be formed on the first-third insulating layer 13 and may overlap with the first semiconductor pattern A1. The first-fourth insulating layer 14 may be formed on the first-third insulating layer 13. The first-fourth insulating layer 14 may be formed to cover the first gate G1. The first-fifth insulating layer 15 may be formed on the first-fourth insulating layer 14.

Each of the first-third insulating layer 13, the first-fourth insulating layer 14, and the first-fifth insulating layer 15 may include one of silicon nitride and silicon oxide, or one insulating layer may include the multiple inorganic layers, but it should not be limited thereto or thereby. The multiple inorganic layers may have the structure in which the layer including silicon nitride and the layer including silicon oxide are alternately stacked.

The first gate G1 may include a metal material. The metal material may include one of molybdenum and titanium. According to one or more embodiments, the first gate G1 may include multiple metal layers. As an example, a lower layer may include titanium, and an upper layer may include molybdenum.

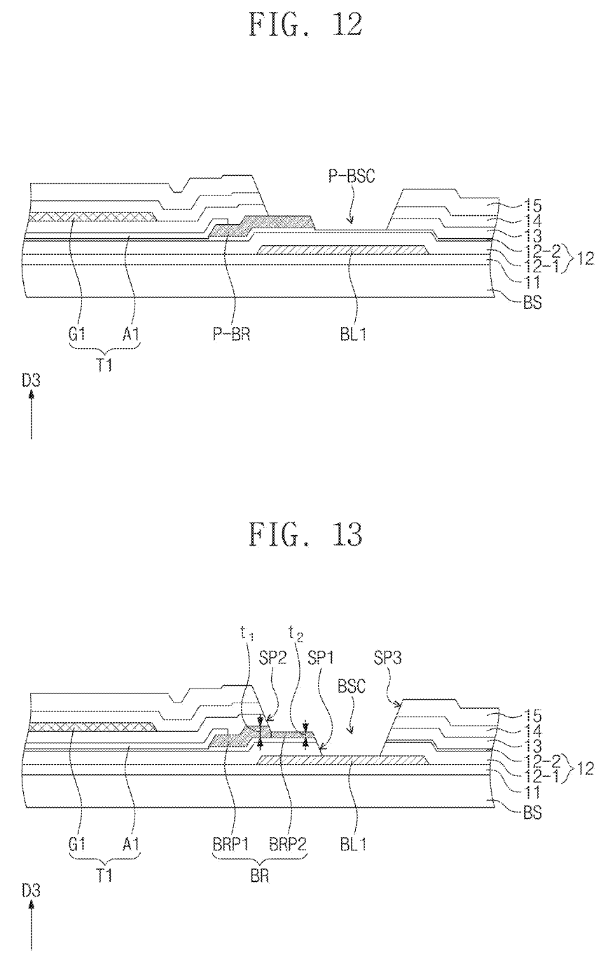

FIG. 12 is a schematic diagram showing the forming of the preliminary contact hole P-BSC.

Referring to FIG. 12, the preliminary contact hole P-BSC may be formed through a dry-etching process. In the process of forming the preliminary contact hole P-BSC, a dry-etching process with a fast etch rate may be applied, even if the selectivity with respect to the preliminary bridge pattern P-BR is low, until just before the preliminary bridge pattern P-BR is exposed. In the process of forming the preliminary contact hole P-BSC, the preliminary bridge pattern P-BR may remain unetched.

The preliminary contact hole P-BSC may penetrate through at least the first-third insulating layer 13 and the first-fourth insulating layer 14. As shown in FIG. 12, the preliminary contact hole P-BSC may penetrate through the first-third insulating layer 13, the first-fourth insulating layer 14, and the first-fifth insulating layer 15. The preliminary bridge pattern P-BR and the second inorganic layer 12-2 may be exposed through the preliminary contact hole P-BSC. The preliminary contact hole P-BSC may be spaced apart from the first semiconductor pattern A1, and thus, the first semiconductor pattern A1 may not be exposed.

FIG. 13 is a schematic diagram showing the forming of the contact hole BSC.

Referring to FIG. 13, the preliminary contact hole P-BSC may be dry-etched to form the contact hole BSC through which the first conductive pattern BL1 is exposed. In the forming of the contact hole BSC (e.g., right after the preliminary bridge pattern P-BR is exposed), the dry-etching process may be performed under conditions that provide high selectivity with respect to the preliminary bridge pattern P-BR to etch the second inorganic layer 12-2 and the first inorganic layer 12-1. In the dry-etching process, the preliminary bridge pattern P-BR may be partially etched to form the bridge pattern BR.

The contact hole BSC may penetrate through the first-second insulating layer 12, the first-third insulating layer 13, the first-fourth insulating layer 14, and the first-fifth insulating layer 15. The first conductive pattern BL1 may be exposed through the contact hole BSC. The bridge pattern BR may be exposed through the contact hole BSC. The side surfaces of the first-second to first-fifth insulating layers 12 to 15 may be exposed through the contact hole BSC.

The bridge pattern BR may include the first bridge portion BRP1 and the second bridge portion BRP2. Because the first bridge portion BRP1 is not exposed through the preliminary contact hole P-BSC, the first bridge portion BRP1 may not be etched during the process of forming the contact hole BSC, and thus may maintain the same thickness as the preliminary bridge pattern P-BR. The second bridge portion BRP2 may be the portion that is exposed through the preliminary contact hole P-BSC and that is partially etched during the forming of the contact hole BSC, and thus may be thinner. The thickness t₁ of the first bridge portion BRP1 may be greater than the thickness t₂ of the second bridge portion BRP2.

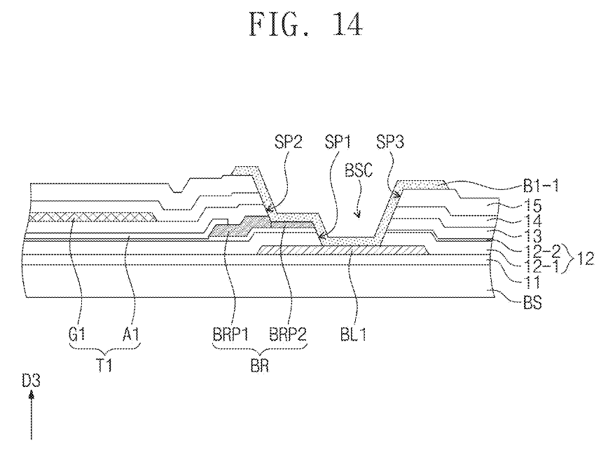

FIG. 14 is a schematic diagram showing the forming of the first-first connection pattern B1-1.

Referring to FIG. 14, the first-first connection pattern B1-1 may be formed in the contact hole BSC to cover the first side portion SP1, the second side portion SP2, and the third side portion SP3. The first-first connection pattern B1-1 may contact the exposed first conductive pattern BL1 and the exposed bridge pattern BR. Accordingly, the first conductive pattern BL1 may be electrically connected to the first semiconductor pattern A1 through the bridge pattern BR in one contact hole BSC.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present present disclosure shall be determined according to the attached claims, with functional equivalents thereof to be included therein.

What is claimed is:

1. A display panel comprising:
a base layer;
a circuit element layer above the base layer; and
a light-emitting element layer comprising a light-emitting element above the circuit element layer,
wherein the circuit element layer comprises:
a conductive pattern above the base layer;
a first insulating layer above the conductive pattern;
a second insulating layer above the first insulating layer;
a first transistor comprising a first semiconductor pattern above the second insulating layer, and a first gate overlapping the first semiconductor pattern;
a third insulating layer covering the first semiconductor pattern;
a fourth insulating layer covering the first gate;
a bridge pattern between the second insulating layer and the first semiconductor pattern, and comprising molybdenum (Mo) or titanium (Ti);
a contact hole penetrating through the first insulating layer, the second insulating layer, the third insulating layer, and the fourth insulating layer, and exposing a portion of the bridge pattern and a portion of the conductive pattern; and
a connection pattern in the contact hole and electrically connecting the bridge pattern and the conductive pattern.

2. The display panel of claim 1, wherein the bridge pattern comprises:
a first bridge portion covered by the third insulating layer; and
a second bridge portion exposed through the contact hole, and having a thickness that is less than a thickness of the first bridge portion.

3. The display panel of claim 2, wherein the thickness of the first bridge portion is greater than a thickness of the first semiconductor pattern.

4. The display panel of claim 2, wherein the first semiconductor pattern contacts the first bridge portion.

5. The display panel of claim 1, wherein the second insulating layer comprises:
a first insulation portion that does not overlap the bridge pattern; and
a second insulation portion overlapping the bridge pattern, and having at thickness that is greater than a thickness of the first insulation portion.

6. The display panel of claim 1, wherein the connection pattern is spaced apart from the first semiconductor pattern.

7. The display panel of claim 1, wherein the connection pattern is electrically connected to the first semiconductor pattern via the bridge pattern.

8. The display panel of claim 1, wherein the first semiconductor pattern comprises an oxide semiconductor.

9. The display panel of claim 1, wherein the first semiconductor pattern comprises indium gallium zinc oxide (IGZO).

10. The display panel of claim 1, wherein the first insulating layer comprises silicon nitride, and
wherein the second insulating layer comprises silicon oxide.

11. An electronic device comprising:
a display panel comprising a base layer, a circuit element layer above the base layer, and a light-emitting element layer comprising a light-emitting element above the circuit element layer; and
a housing accommodating the display panel,
wherein the circuit element layer comprising:
a conductive pattern above the base layer;
a first insulating layer above the conductive pattern;
a second insulating layer above the first insulating layer, and comprising a first insulation portion, and a second insulation portion having a thickness that is greater than a thickness of the first insulation portion;
a first transistor comprising a first semiconductor pattern above the second insulating layer, and a first gate overlapping the first semiconductor pattern;
a third insulating layer covering the first semiconductor pattern;
a fourth insulating layer covering the first gate;
a bridge pattern between the second insulating layer and the first semiconductor pattern, not overlapping the first insulation portion, overlapping the second insulation portion, and comprising a first bridge portion covered by the third insulating layer, and a second bridge portion having a thickness that is less than a thickness of the first bridge portion;
a contact hole penetrating through the first insulating layer, the second insulating layer, the third insulating layer, and the fourth insulating layer, and exposing the second bridge portion and a portion of the conductive pattern; and
a connection pattern in the contact hole, and electrically connecting the bridge pattern and the conductive pattern.

12. The electronic device of claim 11, wherein the bridge pattern comprises molybdenum (Mo) or titanium (Ti),
wherein the first semiconductor pattern comprises an oxide semiconductor,
wherein the first insulating layer comprises silicon nitride, and
wherein the second insulating layer comprises silicon oxide.

13. The electronic device of claim 11, wherein the connection pattern is electrically connected to the first semiconductor pattern via the bridge pattern.

14. The electronic device of claim 11, further comprising at least one of a processor, a memory, or a power module.

15. The electronic device of claim 11, wherein the electronic device comprises a television, a monitor, an outdoor billboard, a personal computer, a notebook computer, a personal digital assistant, a car dashboard, a center fascia, a navigation unit, a room mirror display, a game unit, a smartphone, a tablet computer, a smart watch, a smart glasses, a head-mounted display, or a camera.

16. A method of manufacturing a display panel, the method comprising:
forming a preliminary bridge pattern comprising molybdenum (Mo) or titanium (Ti) on a preliminary display panel comprising a base layer, a conductive pattern above the base layer, a first insulating layer above the conductive pattern, and a second insulating layer above the first insulating layer;
forming a first semiconductor pattern comprising an oxide semiconductor above the second insulating layer to contact the preliminary bridge pattern;
forming a third insulating layer to cover the preliminary bridge pattern and the first semiconductor pattern;
forming a first gate above the third insulating layer to overlap with the first semiconductor pattern;
forming a fourth insulating layer to cover the first gate;
forming a preliminary contact hole through the fourth insulating layer and the third insulating layer to expose a portion of the preliminary bridge pattern and a portion of the second insulating layer; and
forming a contact hole through the second insulating layer and the first insulating layer from the preliminary contact hole to expose a portion of the conductive pattern and a portion of a bridge pattern formed from the exposed portion of the preliminary bridge pattern.

17. The method of claim 16, further comprising forming a connection pattern in the contact hole to electrically connect the bridge pattern and the conductive pattern.

18. The method of claim 16, wherein the forming of the preliminary bridge pattern comprises:
depositing a bridge metal layer above the second insulating layer;
dry-etching the bridge metal layer to pattern the bridge metal layer; and
cleaning the bridge metal layer, and
wherein a first insulation portion of the second insulating layer, which is exposed without being covered by the preliminary bridge pattern, is etched in the cleaning, and has a thickness that is less than a second insulation portion of the second insulating layer, which is covered by the preliminary bridge pattern.

19. The method of claim 16, wherein the preliminary contact hole is spaced from the first semiconductor pattern in the forming of the preliminary contact hole.

20. The method of claim 16, wherein the portion of the preliminary bridge pattern, which is exposed through the preliminary contact hole, is substantially simultaneously etched with the second insulating layer or the first insulating layer in the forming of the contact hole.
